(19) United States
(12) Patent Application Publication
(10) Pub. No.: US 2026/0201545 A1
(43) Pub. Date: Jul. 16, 2026

(54) SUBSTRATE PROCESSING APPARATUS AND A SUBSTRATE PROCESSING METHOD

(71) Applicant: Tokyo Electron Limited, Tokyo (JP)

(72) Inventor: Yoshiaki DAIGO, Tokyo (JP)

(73) Assignee: Tokyo Electron Limited, Tokyo (JP)

(21) Appl. No.: 19/560,197

(22) Filed: Mar. 9, 2026

Related U.S. Application Data
(63) Continuation of application No. PCT/JP2024/032536, filed on Sep. 11, 2024.

(30) Foreign Application Priority Data
Sep. 22, 2023 (JP) 2023-158355

(51) Int. Cl. C23C 14/56; C23C 14/34; C23C 14/50

(52) U.S. Cl. CPC C23C 14/564; C23C 14/3407; C23C 14/505

(57) ABSTRACT

A substrate processing apparatus includes a chamber; a substrate support disposed in the chamber and including a substrate support surface; a rotation unit configured to rotate the substrate support; a processing gas supply configured to supply a processing gas toward the substrate support surface; a target disposed above the substrate support surface of the substrate support, the target having a surface disposed along a flow of the processing gas; and a rectifying gas supply configured to supply a rectifying gas into the chamber and rectify the processing gas passing through the surface of the target in a direction toward the substrate support surface.

### CROSS-REFERENCE TO RELATED APPLICATIONS

This application is a bypass continuation application of international application No. PCT/JP2024/032536 having an international filing date of Sep. 11, 2024 and designating the United States, the international application being based upon and claiming the benefit of priority from Japanese Patent Application No. 2023-158355, filed on Sep. 22, 2023, the entire contents of each of which are incorporated herein by reference.

### BACKGROUND

### Field

An exemplary embodiment of the present disclosure relates to a substrate processing apparatus and a substrate processing method.

### Description of Related Art

In a sputtering apparatus, there is a technique described in JP2003-342722A as a technique of releasing sputter particles and sputter gas from an opening of a cylindrical target and causing the sputter particles and sputter gas to reach a substrate.

### SUMMARY

A substrate processing apparatus in one exemplary embodiment of the present disclosure includes a chamber; a substrate support disposed in the chamber and including a substrate support surface; a rotation unit configured to rotate the substrate support; a processing gas supply configured to supply a processing gas toward the substrate support surface; a target disposed above the substrate support surface of the substrate support, the target having a surface disposed along a flow of the processing gas; and a rectifying gas supply configured to supply a rectifying gas into the chamber and rectify the processing gas passing through the surface of the target in a direction toward the substrate support surface.

### BRIEF DESCRIPTION OF DRAWINGS

FIG. 1 is a diagram for describing a configuration example of a substrate processing apparatus.

FIG. 2 is a diagram for describing a configuration example of a gas introduction unit.

FIG. 3 is a diagram for describing an example of a flowchart of a substrate processing method.

FIG. 4 is a diagram for describing an example of a flowchart of a step ST2 in the substrate processing method.

FIG. 5 is a diagram for describing an example of behavior of sputter particles on a surface layer of a substrate.

FIG. 6 is a diagram for describing another configuration example of the gas introduction unit.

FIG. 7 is a diagram for describing another configuration example of a target.

### DETAILED DESCRIPTION

Hereinafter, each embodiment according to the present disclosure will be described.

In one exemplary embodiment, a substrate processing apparatus is provided, the substrate processing apparatus including: a chamber; a substrate support disposed in the chamber and including a substrate support surface; a rotation unit configured to rotate the substrate support; a processing gas supply configured to supply a processing gas toward the substrate support surface; a target disposed above the substrate support surface of the substrate support, the target having a surface disposed along a flow of the processing gas; and a rectifying gas supply configured to supply a rectifying gas into the chamber and rectify the processing gas passing through the surface of the target in a direction toward the substrate support surface.

In one exemplary embodiment, the surface of the target is disposed perpendicular to the substrate support surface.

In one exemplary embodiment, a plurality of the targets is disposed.

In one exemplary embodiment, the target has a cylindrical shape, and the processing gas passes through an inside of the target.

In one exemplary embodiment, the target has a pair of flat plates facing each other, and the processing gas passes through an inside of the pair of flat plates.

In one exemplary embodiment, the rectifying gas supply is disposed above the substrate support and is configured to supply the rectifying gas toward the substrate support.

In one exemplary embodiment, the rectifying gas supply supplies the rectifying gas to flow around the processing gas.

In one exemplary embodiment, the rectifying gas supply has a rectifying gas supply port through which the rectifying gas is supplied toward the substrate support surface of the substrate support.

In one exemplary embodiment, the processing gas supply has a processing gas supply port through which the processing gas flows out, and the rectifying gas supply port is disposed in the vicinity of the processing gas supply port.

In one exemplary embodiment, the rectifying gas supply port is disposed to surround the processing gas supply port.

In one exemplary embodiment, the processing gas supply port has a larger diameter than the rectifying gas supply port.

In one exemplary embodiment, the rectifying gas supply further has a rectifying gas supply port through which the rectifying gas is supplied toward an outside of the substrate support surface.

In one exemplary embodiment, the rectifying gas includes a gas involved in the film forming processing of the substrate.

In one exemplary embodiment, the substrate processing apparatus further includes a gas introduction unit disposed above the substrate support, in which the gas introduction unit includes the target, and the rectifying gas supply.

In one exemplary embodiment, the rotation unit is configured to rotate the substrate support at 300 rpm or more.

In one exemplary embodiment, the substrate processing apparatus further includes a liner disposed outside the substrate support and inside a side wall of the chamber.

In one exemplary embodiment, the substrate processing apparatus further includes an exhaust unit configured to exhaust an atmosphere in the chamber through a space between the substrate support and a side wall of the chamber.

In an exemplary embodiment, a substrate processing method is provided, the method including: (a) providing a substrate on a substrate support; and (b) supplying a processing gas to the substrate on the substrate support to process the substrate while rotating the substrate support, in which the (b) includes (b-1) flowing the processing gas along a surface of a target, releasing sputter particles from the surface of the target by using a plasma formed from the processing gas, and allowing the processing gas including the sputter particles to flow out from a processing gas supply port of the target toward the substrate, and (b-2) rectifying the processing gas flowed out from the processing gas supply port of the target in a direction toward the substrate by a rectifying gas.

In one exemplary embodiment, in the (b-2), the rectifying gas flows toward the substrate to surround a periphery of the processing gas.

In one exemplary embodiment, in the (b), the substrate support is rotated at 300 rpm or more.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### Example of Substrate Processing Apparatus

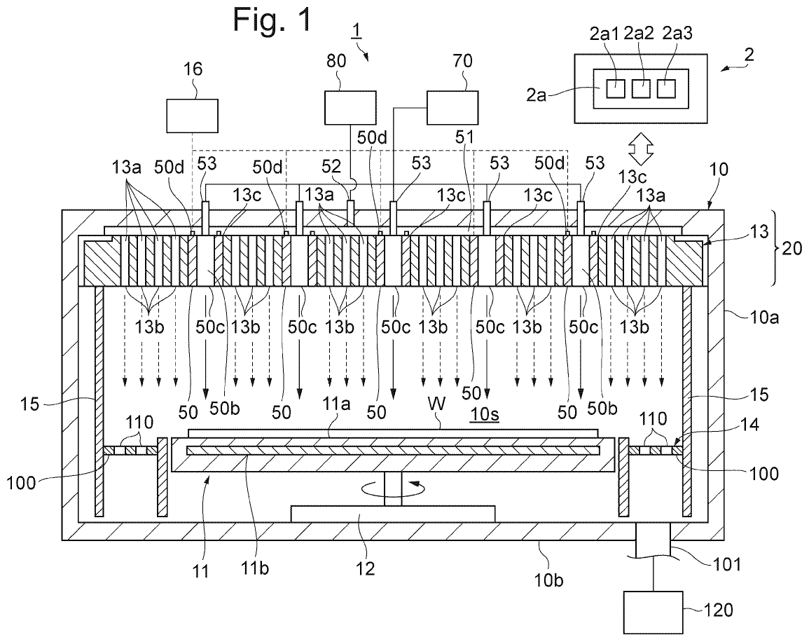

FIG. 1 is a diagram for describing a configuration example of a substrate processing apparatus 1. In an embodiment, the substrate processing apparatus 1 is a film forming processing apparatus that performs film forming processing on a substrate. In an embodiment, the substrate processing apparatus 1 is a sputter apparatus that performs sputtering processing on the substrate.

In an embodiment, the substrate processing apparatus 1 includes a chamber 10, a substrate support 11, a rotation unit 12, a gas introduction unit 20, an exhaust unit 14, a liner 15, a power supply 16, and a controller 2.

The chamber 10 is configured to form a processing space 10s therein. The substrate support 11 is disposed in the chamber 10. The substrate support 11 is disposed at a lower portion of the processing space 10s.

In an embodiment, the substrate support 11 has a substrate support surface 11a that supports a substrate W on an upper surface thereof. The substrate support 11 has an electrostatic chuck 11b. The electrostatic chuck 11b includes an insulating member and an electrostatic electrode disposed in the insulating member. The substrate support 11 has a disk shape having a thickness in a vertical direction (up-down direction).

In an embodiment, the rotation unit 12 is configured to rotate the substrate support 11 around a center axis of the substrate support 11. The rotation unit 12 can rotate the substrate support 11 at 300 rpm or more. The rotation unit 12 has a support member (rotation shaft) that supports the substrate support 11, a motor that rotates the support member, and the like.

The gas introduction unit 20 includes a processing gas supply and a rectifying gas supply. In an embodiment, the gas introduction unit 20 is disposed above the substrate support surface 11a of the substrate support 11. The gas introduction unit 20 has a rectifying plate 13 having a disk shape with a thickness in a vertical direction. The rectifying plate 13 has a diameter larger than that of the substrate support 11. The rectifying plate 13 is made of an insulating material. In an embodiment, the rectifying plate 13 has at least one rectifying gas supply hole 13a, at least one rectifying gas supply port 13b, and at least one target housing 13c.

The rectifying plate 13 has at least one target 50. In an embodiment, a plurality of targets 50 is provided on the rectifying plate 13. The rectifying plate 13 has a plurality of target housings 13c. The target housing 13c is formed to penetrate the rectifying plate 13 in the vertical direction. The target 50 is provided in the target housing 13c. The target 50 may have a cylindrical shape. In an embodiment, the processing gas supply hole 50b is configured to penetrate an inside of the target 50. That is, an inner surface of the target 50 is disposed along a flow of a processing gas. The target 50 is disposed in such a manner that the center axis thereof is directed in the vertical direction. The inner surface of the target 50 is disposed perpendicular to the substrate support surface 11a. The processing gas supply port 50c is open to a lower surface of the processing gas supply hole 50b. The processing gas supply port 50c is open to a lower surface of the rectifying plate 13. The processing gas supply port 50c is directed toward the substrate support surface 11a. In an embodiment, the processing gas supply is configured of the processing gas supply hole 50b and the processing gas supply port 50c. The target 50 may be made of a metal material, a semiconductor material, a ceramic material, an insulating material, or the like. When forming a silicon carbide (SiC) film, a SiC target can be used. In addition, when forming the silicon carbide (SiC) film, the Si target and the C target may be used at the same time. When forming a gallium nitride (GaN) film, a GaN target can be used. When forming an aluminum nitride (AlN) film, an Al target can be used. When forming a silicon dioxide (SiO₂) film, a Si target can be used. In addition, when forming the silicon dioxide (SiO₂) film, a SiO₂ target may be used.

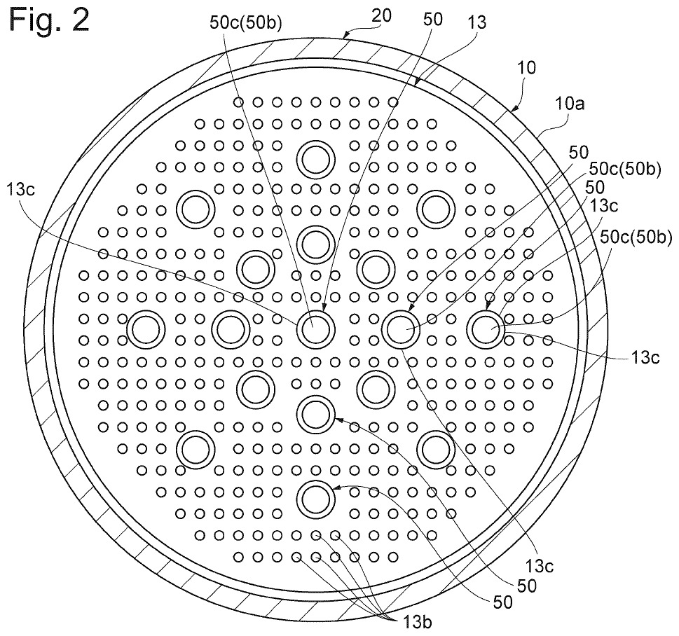

FIG. 2 is a diagram for describing a configuration example of the gas introduction unit 20. FIG. 2 is a diagram of an example of the gas introduction unit 20 as viewed from below. As illustrated in FIG. 2, the plurality of targets 50 is disposed at intervals from each other in the rectifying plate 13. The plurality of targets 50 is disposed in a plane of the rectifying plate 13 without bias. One of the targets 50 may be located at a center of the rectifying plate 13. In addition, the plurality of targets 50 may be disposed around the center of the rectifying plate 13 along a radial direction and a circumferential direction. In addition, the plurality of targets 50 may be disposed in vertical and lateral directions orthogonal to each other in the plane of the rectifying plate 13.

As illustrated in FIG. 1, in an embodiment, the processing gas supply hole 50b is connected to at least one processing gas supply system 70 via a processing gas inlet 53. The processing gas supply system 70 is configured to supply the processing gas to the processing gas supply hole 50b via the processing gas inlet 53. The processing gas supply system 70 may have a gas source or a gas flow rate controller. The processing gas may be a gas that contributes to the film forming processing of the substrate W. The processing gas may include a rare gas such as argon gas and a reactive gas such as a nitrogen gas, an oxygen gas, or a hydrogen gas. When forming a silicon carbide film (SiC film) on the substrate W, the processing gas may include an argon gas. When forming the gallium nitride film (GaN film) or the aluminum nitride (AlN) film on the substrate W, the processing gas may include the argon gas and the nitrogen gas. When forming the silicon dioxide (SiO₂) film, the processing gas may include the argon gas and an oxygen gas.

The target 50 may have an electrode 50d electrically connected to the power supply 16. In an embodiment, by applying a voltage from the power supply 16 to the electrode 50d, a plasma is formed from the processing gas flowing inside the processing gas supply hole 50b, and ions of the plasma collide with the inner surface of the target 50 and are sputtered, and thereby the sputter particles can be released from the inner surface of the target 50. In an embodiment, the target 50 can release the processing gas including the sputter particles from the processing gas supply port 50c toward the substrate support surface 11a below.

The rectifying gas supply is configured to supply a rectifying gas for rectifying the processing gas flowing out from the processing gas supply port 50c into the chamber 10. The rectifying gas supply is disposed above the substrate support 11 and is configured to supply the rectifying gas toward the substrate support 11. In an embodiment, the rectifying gas supply is configured of a rectifying gas supply hole 13a and a rectifying gas supply port 13b.

The rectifying gas supply hole 13a is formed to penetrate the rectifying plate 13 in the vertical direction. A length of the rectifying gas supply hole 13a in the vertical direction may be the same as that of the target 50. The rectifying gas supply port 13b is open at a lower end of the rectifying gas supply hole 13a. The rectifying gas supply port 13b is open to the lower surface of the rectifying plate 13.

As illustrated in FIGS. 1 and 2, the rectifying gas supply port 13b may be disposed in the vicinity of the processing gas supply port 50c to surround the processing gas supply port 50c. A part of the rectifying gas supply port 13b is disposed at a position that does not face the substrate support surface 11a, that is, thereby the rectifying gas is supplied toward an outer region of the substrate support surface 11a. The processing gas supply port 50c may have a larger diameter than the rectifying gas supply port 13b.

As illustrated in FIG. 1, in the embodiment, the chamber 10 has at least one rectifying gas diffusion chamber 51. The rectifying gas diffusion chamber 51 is provided on an upper portion of the rectifying plate 13. The rectifying gas supply hole 13a communicates with the rectifying gas diffusion chamber 51. The rectifying gas diffusion chamber 51 may be provided outside the chamber 10.

In an embodiment, the rectifying gas supply hole 13a is connected to at least one rectifying gas supply system 80 via the rectifying gas diffusion chamber 51 and the rectifying gas inlet 52. The rectifying gas supply system 80 has a gas source and a gas flow rate controller.

As illustrated in FIG. 1, in an embodiment, the rectifying gas is supplied from the rectifying gas supply system 80 to the rectifying gas inlet 52, and flows out from each of the rectifying gas supply ports 13b downward through the rectifying gas diffusion chamber 51 and the plurality of rectifying gas supply holes 13a. The rectifying gas may be a gas not involved in the film forming processing of the substrate. The rectifying gas may include a gas containing an element incorporated into the film to be formed. When forming an N-type silicon carbide film on the substrate W, the rectifying gas may contain the argon gas and the nitrogen gas. When forming the silicon oxide film, the rectifying gas may contain the argon gas and the oxygen gas.

In an embodiment, the exhaust unit 14 is configured to exhaust the atmosphere of the processing space 10s in the chamber 10 through a space between the substrate support 11 and a side wall 10a of the chamber 10. The exhaust unit 14 has a baffle plate 100 and a gas exhaust port 101.

The baffle plate 100 is disposed between the substrate support 11 and the side wall 10a of the chamber 10. The baffle plate 100 has an annular plate shape to surround an outer periphery of the substrate support 11. A plurality of openings 110 penetrating the baffle plate 100 in the vertical direction is formed. The opening 110 may be a round hole or a slit shape long in the radial direction.

The gas exhaust port 101 is provided in a bottom portion 10b of the chamber 10. The gas exhaust port 101 is disposed below the baffle plate 100. One or a plurality of gas exhaust ports 101 may be provided around the substrate support 11 in plan view. The plurality of gas exhaust ports 101 is disposed at equal intervals around the substrate support 11 in plan view. The gas exhaust port 101 is connected to an exhaust system 120. The exhaust system 120 includes a pressure adjusting valve and a vacuum pump. The exhaust system 120 can depressurize the processing space 10s of the chamber 10 to a range of 10 Pa or more and 5 kPa or less.

A purge gas line (not illustrated) may be connected to a space below the substrate support 11 in the chamber 10. The processing gas can be prevented from being deposited in a region below the substrate support 11 by the purge gas supplied from the purge gas line.

The liner 15 is disposed outside the substrate support 11 and inside the side wall 10a of the chamber 10. The liner 15 has a cylindrical shape. The liner 15 extends in the vertical direction from the vicinity of the bottom portion 10b of the chamber 10 to the vicinity of the gas introduction unit 20. The liner 15 may be divided into upper and lower parts in the vicinity of a height of the substrate support 11, and an up-down drive mechanism (not illustrated) may be provided in the lower liner and thereby a transport port can be formed between the upper liner and the lower liner, and the substrate W may be carried in and out of the chamber 10 through the transport port.

The power supply 16 has a DC power supply and/or an RF power supply. The DC power supply is configured to supply a DC signal to the electrode 50d of the target 50, and the RF power supply is configured to supply an RF signal to the electrode 50d of the target 50 via a matching circuit (not illustrated). The DC power supply may include a pulse DC power source.

The controller 2 processes a computer-executable command for causing the substrate processing apparatus 1 to execute various steps described in the present disclosure. The controller 2 may be configured to control each element of the substrate processing apparatus 1 to execute various steps described here. In an embodiment, a part or all of the controller 2 may be included in the substrate processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired via a medium when necessary. The acquired program is stored in the storage 2a2, is read out from the storage 2a2, and executed by the processor 2a1. The medium may be various storage media readable by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the substrate processing apparatus 1 via a communication line such as a local area network (LAN).

### Example of Substrate Processing Method

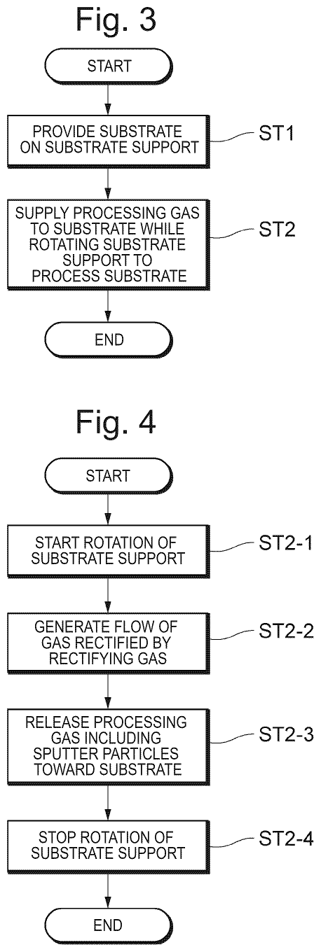

FIG. 3 is a flowchart illustrating an example of a substrate processing method (hereinafter, also referred to as “the present processing method”) according to one exemplary embodiment. As illustrated in FIG. 3, in an embodiment, the present processing method includes a step ST1 of providing the substrate W on the substrate support 11, and a step ST2 of processing the substrate W while rotating the substrate support 11. The present processing method may be film forming processing on the substrate W. The present processing method is executed by the substrate processing apparatus 1 illustrated in FIG. 1. The controller 2 controls each unit of the substrate processing apparatus 1 to execute the present processing method on the substrate W.

### (Step ST1: Provision of Substrate)

In an embodiment, in the step ST1, the substrate W is provided in the chamber 10 of the substrate processing apparatus 1. The substrate W is provided on the substrate support surface 11a of the substrate support 11. The substrate W is held in the substrate support 11 by the electrostatic chuck 11b.

After the substrate W is provided to the substrate support 11 or before the substrate W is provided to the substrate support 11, a temperature of the substrate support 11 or the substrate W is adjusted to a set temperature by a temperature-controlled module or the like. The set temperature may be in the range of 0° C. or higher and 2000° C. or lower. In addition, a pressure in the chamber 10 may be reduced to the range of 10 Pa or higher and 5 kPa or lower by the exhaust system 120.

### (Step ST2: Film Forming Processing of Substrate)

In the step ST2, while the substrate support 11 is rotated, the substrate W on the substrate support 11 is subjected to the film forming processing by supplying the processing gas to the substrate W. FIG. 4 is a flowchart illustrating an example of the step ST2. As illustrated in FIG. 4, the step ST2 includes a step ST2-1 of rotating the substrate support 11, a step ST2-2 of generating a flow of a gas rectified by the rectifying gas, a step ST2-3 of allowing the processing gas including the sputter particles to flow out from the processing gas supply port 50c toward the substrate W, and a step ST2-4 of stopping the rotation of the substrate support 11. The step ST2-2 and the step ST2-3 may be performed at the same time. In addition, the start of the supply of the rectifying gas in the step ST2-2 may be before the start of the supply of the processing gas in the step ST2-3.

In an embodiment, in the step ST2-1, the substrate support 11 (the substrate W) is rotated at a high speed by the rotation unit 12 at 300 rpm or more, preferably in the range of 300 rpm or more and 2000 rpm or less.

In an embodiment, in the step ST2-2, the rectifying gas is supplied into the chamber 10 by the rectifying gas supply. The rectifying gas flows from each rectifying gas supply port 13b toward the substrate W and the outer periphery thereof through the rectifying gas inlet 52, the rectifying gas diffusion chamber 51, and each rectifying gas supply hole 13a.

In an embodiment, in the step ST2-3, the processing gas supplied by the processing gas supply system 70 illustrated in FIG. 1 is supplied to the chamber 10 via the processing gas inlet 53 and flows through the processing gas supply hole 50b. In addition, a voltage is applied to the electrode 50d of the target 50 by the power supply 16. In this case, the plasma is formed from a part of the processing gas, and the ion particles of the plasma collide with the surface of the target 50. As a result, sputter particles are released from the surface of the target 50. The sputter particles are released from the processing gas supply port 50c toward the substrate W on the substrate support surface 11a together with the processing gas.

The rectifying gas which is described above flows in the same downward direction as the processing gas to surround the periphery of the processing gas that has flowed out from the processing gas supply port 50c. The processing gas is rectified by the rectifying gas, and reaches the surface of the substrate W by suppressing convection and diffusion.

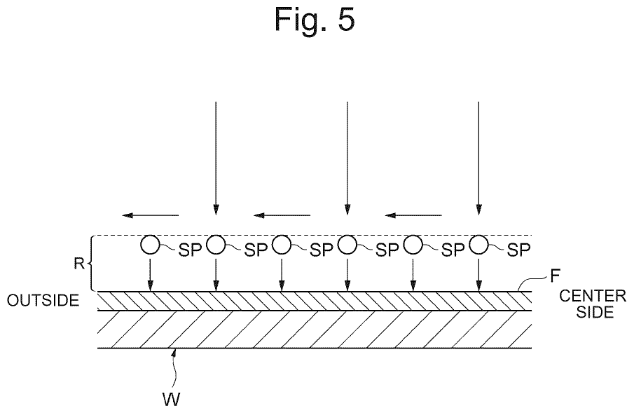

As illustrated in FIG. 5, the substrate W is rotated at a high speed of 300 rpm or more, and the processing gas is rectified and reaches the substrate W, whereby the sputter particles SP are uniformly and sufficiently supplied to the surface of the substrate W. In this case, a boundary layer R having a thin and uniform thickness is formed on the surface layer of the substrate W due to the high-speed rotation of the substrate W. Due to the thin and uniform boundary layer R, the sputter particles SP are supplied to the surface of the substrate W in a short time and uniformly. In this way, a uniform film F is formed on the surface of the substrate W in a short time by the processing gas including the sputter particles SP.

The processing gas including the sputter particles SP in the surface layer of the substrate W flows from the center side to the outside of the substrate W. In addition, the rectifying gas that has flowed out from the rectifying gas supply port 13b of the outer peripheral portion of the gas introduction unit 20 descends through the processing gas or the outer periphery of the rectifying gas that has flowed out from the rectifying gas supply port 13b of the inner peripheral portion of the gas introduction unit 20. The processing gas including the sputter particles SP that have flowed from the center side of the surface layer of the substrate W to the outside of the substrate W and the rectifying gas that has flowed out from the rectifying gas supply port 13b of the outer peripheral portion of the gas introduction unit 20 are joined together and are exhausted from the gas exhaust port 101 through the baffle plate 100 outside the substrate support 11 illustrated in FIG. 1. The rectifying gas that has flowed out from the rectifying gas supply port 13b of the outer peripheral portion of the gas introduction unit 20 suppresses the convection of the processing gas including the sputter particles SP. This also allows the sputter particles SP or the processing gas to be uniformly supplied to the surface of the substrate W, and a uniform film F is formed.

In the step ST2-4, the rotation of the substrate support 11 is stopped.

According to the present exemplary embodiment, the substrate processing apparatus 1 includes the substrate support 11, the rotation unit 12, the processing gas supply, the target 50, and the rectifying gas supply. As a result, the processing gas including the sputter particles SP can be rectified and supplied to the substrate W while rotating the substrate W, and thus the uniformity in the substrate surface in the film forming processing of the substrate can be improved.

In an embodiment, since the plurality of targets 50 is disposed, the uniformity in the substrate surface in the film forming processing of the substrate can be improved.

In an embodiment, since the rectifying gas supply supplies the rectifying gas to flow around the processing gas, the diffusion and convection of the processing gas can be suppressed, and the processing gas can be rectified in a direction toward the substrate W.

In an embodiment, since the rectifying gas supply port 13b is disposed in the vicinity of the processing gas supply port 50c, the processing gas can be rectified in a direction toward the substrate W.

In an embodiment, since the rectifying gas supply port 13b is disposed to surround the processing gas supply port 50c, the processing gas can be rectified in a direction toward the substrate W.

In an embodiment, the processing gas supply hole 50b and the processing gas supply port 50c have a larger diameter than the rectifying gas supply hole 13a and the rectifying gas supply port 13b. The rectifying gas supply hole 13a and the rectifying gas supply port 13b have, for example, a diameter of 1 mm or more and less than 5 mm, and the processing gas supply hole 50b and the processing gas supply port 50c have, for example, a diameter of 5 mm or more and less than 20 mm. In this way, the rectifying effect of the rectifying gas is promoted, and a large change in the conductance of the processing gas supply hole 50b and the processing gas supply port 50c due to the consumption of the target material is suppressed, and thereby the processing gas can be stably supplied to the substrate W.

In an embodiment, since the substrate processing apparatus 1 includes the liner 15 disposed outside the substrate support 11 and inside the side wall 10a of the chamber 10, diffusion and convection of the processing gas can be suppressed. Therefore, it is possible to suppress the adhesion of the reaction product to the side wall 10a of the chamber 10.

In an embodiment, since the rectifying gas supply further has the rectifying gas supply port 13b for supplying the rectifying gas toward the outside of the substrate support surface 11a, the processing gas or the other rectifying gas can be surrounded from the outside, and the diffusion and convection of the processing gas toward the liner 15 can be suppressed. In this manner, it is possible to suppress the adhesion of the reaction product to the inner wall of the liner 15.

In an embodiment, the rectifying gas can also include a part of the gas involved in the film forming processing of the substrate. For example, when forming the silicon dioxide (SiO₂) film, the argon gas can be used as the processing gas, and the oxygen gas and the argon gas can be used as the rectifying gas. By using only the rare gas as the processing gas and including the reactive gas in the rectifying gas, it is possible to form the oxide film or the nitride film while suppressing oxidation or nitridation on the target surface. If oxidation or nitridation on the target surface can be suppressed, the amount of sputter particles released from the target can be increased in many cases, as compared with a case where oxidation or nitridation on the target surface is performed. That is, the film forming speed is increased, and the film forming processing of the substrate can be performed in a short time in many cases.

In an embodiment, since the rotation unit 12 is configured to rotate the substrate support 11 at 300 rpm or more, the boundary layer having a thin and uniform thickness can be formed on the substrate, and a film can be uniformly formed on the substrate W in a short time.

In an embodiment, the substrate processing apparatus 1 includes the exhaust unit 14 configured to exhaust the atmosphere in the chamber 10 through a space between the substrate support 11 and the side wall 10a of the chamber 10. In this manner, the rectifying gas that has flowed out from the rectifying gas supply port 13b of the outer peripheral portion of the gas introduction unit 20 is exhausted from the exhaust unit 14 while suppressing the convection of the processing gas including the sputter particles SP that have flowed from the center side of the surface layer of the substrate W to the outside of the surface layer of the substrate W. Therefore, the sputter particles SP or the processing gas is uniformly supplied to the surface of the substrate W, and the uniform film F is formed.

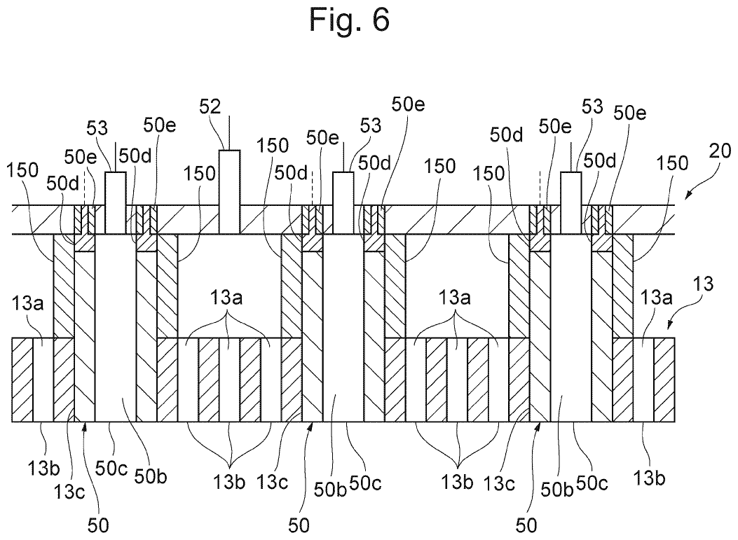

In the gas introduction unit 20 of the above-described embodiment, the target 50 and the rectifying gas supply hole 13a of the rectifying gas have the same length in the vertical direction. However, the length of the target 50 in the vertical direction may be larger than the length of the rectifying gas supply hole 13a in the vertical direction. As illustrated in FIG. 6, for example, the target 50 protrudes above the rectifying gas supply hole 13a. In this case, an annular insulating member 150 is disposed around a protruding portion of the target 50. As a result, the occurrence of discharge between the targets 50 is suppressed. The electrode 50d may be covered with an electrode cover 50e, and the electrode cover 50e can suppress the electrode 50d from coming into contact with a conductive member such as a wall of the chamber.

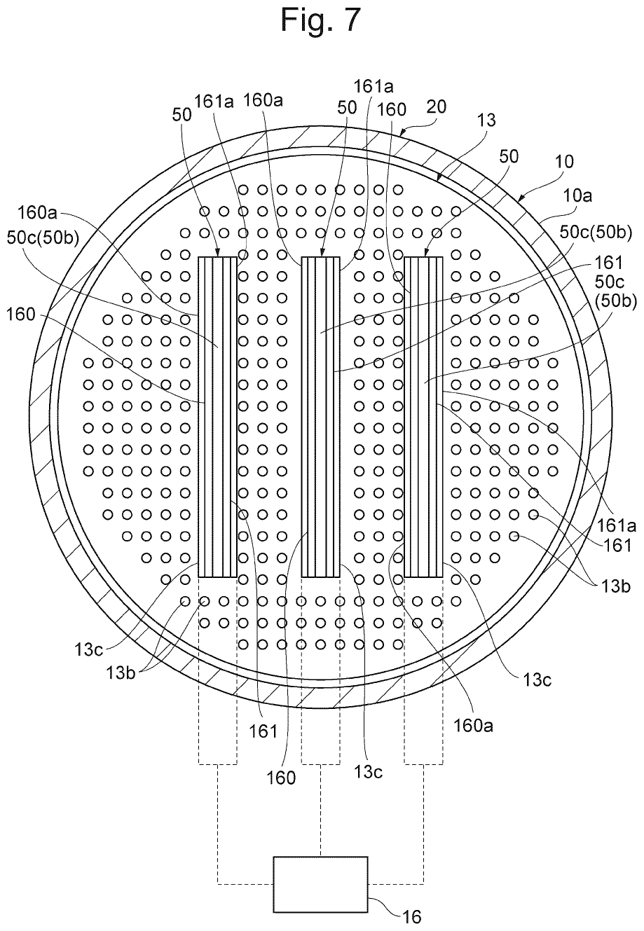

As illustrated in FIG. 7, in the above-described embodiment, the target 50 may be a facing flat plate type having flat plates facing each other. The target 50 has a first flat plate 160 and a second flat plate 161. The first flat plate 160 and the second flat plate 161 include at least a part of the constituent elements of the film to be formed. The first flat plate 160 and the second flat plate 161 are disposed in the target housing 13c of the rectifying plate 13. The first flat plate 160 and the second flat plate 161 are spaced apart from each other, and the processing gas supply hole 50b and the processing gas supply port 50c are formed therebetween. In this case, the processing gas supply hole 50b and the processing gas supply port 50c constitute the processing gas supply. The first flat plate 160 has a first electrode 160a on a back surface opposite to the processing gas supply hole 50b, and the second flat plate 161 has a second electrode 161a on the back surface opposite to the processing gas supply hole 50b. The first electrode 160a and the second electrode 161a are electrically connected to the power supply 16. The plurality of targets 50 may be provided on the rectifying plate 13 of the gas introduction unit 20. The rectifying gas supply hole 13a and the rectifying gas supply port 13b of the rectifying gas may be disposed around the processing gas supply port 50c. The rectifying gas supply hole 13a and the rectifying gas supply port 13b may also be disposed on the outer peripheral portion of the gas introduction unit 20.

The embodiments of the present disclosure further include the following aspects.

### (Addendum 1)

A substrate processing apparatus including:
a chamber;
a substrate support disposed in the chamber and including a substrate support surface;
a rotation unit configured to rotate the substrate support;
a processing gas supply configured to supply a processing gas toward the substrate support surface;
a target disposed above the substrate support surface of the substrate support, the target having a surface disposed along a flow of the processing gas; and
a rectifying gas supply configured to supply a rectifying gas into the chamber and rectify the processing gas passing through the surface of the target in a direction toward the substrate support surface.

### (Addendum 2)

The substrate processing apparatus according to Addendum 1, in which the surface of the target is disposed perpendicular to the substrate support surface.

### (Addendum 3)

The substrate processing apparatus according to Addendum 1 or 2, in which a plurality of the targets is disposed.

### (Addendum 4)

The substrate processing apparatus according to any one of Addenda 1 to 3,
in which the target has a cylindrical shape, and
the processing gas passes through an inside of the target.

### (Addendum 5)

The substrate processing apparatus according to any one of Addenda 1 to 3,
which the target has a pair of flat plates facing each other, and
the processing gas passes through an inside of the pair of flat plates.

### (Addendum 6)

The substrate processing apparatus according to any one of Addenda 1 to 5, in which the rectifying gas supply is disposed above the substrate support and is configured to supply the rectifying gas toward the substrate support.

### (Addendum 7)

The substrate processing apparatus according to Addendum 6, in which the rectifying gas supply supplies the rectifying gas to flow around the processing gas.

### (Addendum 8)

The substrate processing apparatus according to Addendum 6 or 7, in which the rectifying gas supply has a rectifying gas supply port through which the rectifying gas is supplied toward the substrate support surface of the substrate support.

### (Addendum 9)

The substrate processing apparatus according to Addendum 8,
in which the processing gas supply has a processing gas supply port through which the processing gas flows out, and
the rectifying gas supply port is disposed in the vicinity of the processing gas supply port.

### (Addendum 10)

The substrate processing apparatus according to Addendum 9, in which the rectifying gas supply port is disposed to surround the processing gas supply port.

### (Addendum 11)

The substrate processing apparatus according to Addendum 10, in which the processing gas supply port has a larger diameter than the rectifying gas supply port.

### (Addendum 12)

The substrate processing apparatus according to Addendum 8, in which the rectifying gas supply further has a rectifying gas supply port through which the rectifying gas is supplied toward an outside of the substrate support surface.

### (Addendum 13)

The substrate processing apparatus according to any one of Addenda 1 to 12, in which the rectifying gas includes a gas containing an element incorporated into a film to be formed.

### (Addendum 14)

The substrate processing apparatus according to any one of Addenda 1 to 13, further including:
a gas introduction unit disposed above the substrate support,
in which the gas introduction unit includes the target, the processing gas supply, and the rectifying gas supply.

### (Addendum 15)

The substrate processing apparatus according to any one of Addenda 1 to 14, in which the rotation unit is configured to rotate the substrate support at 300 rpm or more.

### (Addendum 16)

The substrate processing apparatus according to any one of Addenda 1 to 15, further including:
a liner disposed outside the substrate support and inside a side wall of the chamber.

### (Addendum 17)

The substrate processing apparatus according to any one of Addenda 1 to 16, further including:
an exhaust unit configured to exhaust an atmosphere in the chamber through a space between the substrate support and a side wall of the chamber.

### (Addendum 18)

A substrate processing method including:
(a) providing a substrate on a substrate support; and
(b) supplying a processing gas to the substrate on the substrate support to process the substrate while rotating the substrate support,
in which the (b) includes
   (b-1) flowing the processing gas along a surface of a target, releasing sputter particles from the surface of the target by using a plasma formed from the processing gas, and allowing the processing gas including the sputter particles to flow out from a processing gas supply port toward the substrate, and
   (b-2) rectifying the processing gas flowed out from the processing gas supply port in a direction toward the substrate by a rectifying gas.

### (Addendum 19)

The substrate processing method according to Addendum 18, in which in the (b-2), the rectifying gas flows toward the substrate to surround a periphery of the processing gas.

### (Addendum 20)

The substrate processing method according to Addendum 18 or 19, in which in the (b), the substrate support is rotated at 300 rpm or more.

Each of the above-described embodiments is described for the purpose of description, and it is not intended to limit the scope of the present disclosure. Each of the above-described embodiments may be modified in various ways without departing from the scope and gist of the present disclosure. For example, some configuration elements in one embodiment can be added to other embodiments. In addition, some configuration elements in one embodiment can be replaced with corresponding configuration elements in another embodiment.

According to one exemplary embodiment of the present disclosure, it is possible to provide a technique capable of improving the uniformity in the substrate surface in the substrate processing.

What is claimed is:

1. A substrate processing apparatus comprising:
a chamber;
a substrate support disposed in the chamber and including a substrate support surface;
a rotation unit configured to rotate the substrate support;
a processing gas supply configured to supply a processing gas toward the substrate support surface;
a target disposed above the substrate support surface of the substrate support, the target having a surface disposed along a flow of the processing gas; and
a rectifying gas supply configured to supply a rectifying gas into the chamber and rectify the processing gas passing through the surface of the target in a direction toward the substrate support surface.

2. The substrate processing apparatus according to claim 1, wherein the surface of the target is disposed perpendicular to the substrate support surface.

3. The substrate processing apparatus according to claim 1, wherein a plurality of the targets is disposed.

4. The substrate processing apparatus according to claim 1, wherein the target has a cylindrical shape, and the processing gas passes through an inside of the target.

5. The substrate processing apparatus according to claim 1, wherein the target has a pair of flat plates facing each other, and the processing gas passes through an inside of the pair of flat plates.

6. The substrate processing apparatus according to claim 1, wherein the rectifying gas supply is disposed above the substrate support and is configured to supply the rectifying gas toward the substrate support.

7. The substrate processing apparatus according to claim 6, wherein the rectifying gas supply supplies the rectifying gas to flow around the processing gas.

8. The substrate processing apparatus according to claim 6, wherein the rectifying gas supply has a rectifying gas supply port through which the rectifying gas is supplied toward the substrate support surface of the substrate support.

9. The substrate processing apparatus according to claim 8,
wherein the processing gas supply has a processing gas supply port through which the processing gas flows out, and
the rectifying gas supply port is disposed in the vicinity of the processing gas supply port.

10. The substrate processing apparatus according to claim 9, wherein the rectifying gas supply port is disposed to surround the processing gas supply port.

11. The substrate processing apparatus according to claim 10, wherein the processing gas supply port has a larger diameter than the rectifying gas supply port.

12. The substrate processing apparatus according to claim 8, wherein the rectifying gas supply further has a rectifying gas supply port through which the rectifying gas is supplied toward an outside of the substrate support surface.

13. The substrate processing apparatus according to claim 1, wherein the rectifying gas includes a gas containing an element incorporated into a film to be formed.

14. The substrate processing apparatus according to claim 1, further comprising:
a gas introduction unit disposed above the substrate support,
wherein the gas introduction unit includes the target, the processing gas supply, and the rectifying gas supply.

15. The substrate processing apparatus according to claim 1, wherein the rotation unit is configured to rotate the substrate support at 300 rpm or more.

16. The substrate processing apparatus according to claim 1, further comprising:
a liner disposed outside the substrate support and inside a side wall of the chamber.

17. The substrate processing apparatus according to claim 1, further comprising:
an exhaust unit configured to exhaust an atmosphere in the chamber through a space between the substrate support and a side wall of the chamber.

18. A substrate processing method comprising:
(a) providing a substrate on a substrate support; and
(b) supplying a processing gas to the substrate on the substrate support to process the substrate while rotating the substrate support,
wherein the (b) includes
(b-1) flowing the processing gas along a surface of a target, releasing sputter particles from the surface of the target by using a plasma formed from the processing gas, and allowing the processing gas including the sputter particles to flow out from a processing gas supply port toward the substrate, and
(b-2) rectifying the processing gas flowed out from the processing gas supply port in a direction toward the substrate by a rectifying gas.

19. The substrate processing method according to claim 18, wherein in the (b-2), the rectifying gas flows toward the substrate to surround a periphery of the processing gas.

20. The substrate processing method according to claim 18, wherein in the (b), the substrate support is rotated at 300 rpm or more.
